(19) United States
(12) Patent Application Publication
(10) Pub. No.: US 2014/0177150 A1
(43) Pub. Date: Jun. 26, 2014

(54) CROSSTALK CANCELATION IN STRIPLINES

(71) Applicants: Olufemi B. Oluwafemi, Hillsboro, OR (US); Richard K. Kunze, Woodinville, WA (US); Henry I. Peng, Portland, OR (US); Karen Navarro Castillo, Tlaquepaque (MX); Adefisayo O. Adepetun, West Columbia, SC (US); Brandon Gore, West Columbia, SC (US); Oluwafemi Akinwale, Milpitas, CA (US)

(72) Inventors: Olufemi B. Oluwafemi, Hillsboro, OR (US); Richard K. Kunze, Woodinville, WA (US); Henry I. Peng, Portland, OR (US); Karen Navarro Castillo, Tlaquepaque (MX); Adefisayo O. Adepetun, West Columbia, SC (US); Brandon Gore, West Columbia, SC (US); Oluwafemi Akinwale, Milpitas, CA (US)

(21) Appl. No.: 13/725,703

(22) Filed: Dec. 21, 2012

(51) Int. Cl. H05K 1/02; H05K 3/30; H05K 7/00

(52) U.S. Cl. CPC H05K 1/0296; H05K 7/00; H05K 3/30
USPC 361/679.02; 174/36; 29/832

(57) ABSTRACT

The present disclosure provides techniques for decreasing vertical crosstalk in a stripline. An apparatus may include a conductor bracketed by ground layers. The conductor may have a horizontal crosstalk. A vertical component may be coupled to the conductor. The vertical component may have a vertical crosstalk cancelled by the horizontal crosstalk.

### TECHNICAL FIELD

The present invention generally relates to stripline transmission lines. In particular, the present invention relates to techniques for reducing crosstalk in stripline systems.

### BACKGROUND

Printed circuit boards may be used in a variety of computing devices, such as laptop computers, desktop computers, mobile phones, tablet computers, and other computing devices. However, the performance of the computing devices may be negatively affected by crosstalk within the printed circuit boards.

### BRIEF DESCRIPTION OF THE DRAWINGS

Certain exemplary embodiments are described in the following detailed description and in reference to the drawings, in which:

FIG. 1 is a diagram of a portion of a circuit board;

FIG. 2 is a cross-sectional view of a portion of a circuit board, illustrating a stripline;

FIG. 3 is a graph illustrating the effect of the relative permittivity of resin on crosstalk polarity;

FIG. 4 is a graph illustrating the effect of signal line spacing on crosstalk polarity;

FIG. 5 is a schematic of a stripline including stubs;

FIG. 6 is a top view of a stripline including stubs;

FIG. 7 is a graph comparing methods of affecting crosstalk polarity; and

FIG. 8 is a process flow diagram of a method of forming a circuit board.

### DETAILED DESCRIPTION OF SPECIFIC EMBODIMENTS

Embodiments disclosed herein provide techniques for reducing crosstalk in stripline systems. High speed performance in a computing system is limited by the negative impact of crosstalk. On a platform, crosstalk can be divided into two components, namely vertical and horizontal. Vertical crosstalk can be attributed to vertical components, such as vias, connectors, and sockets, while horizontal crosstalk is attributed to horizontal components, i.e., signal line to signal line. The combination of horizontal and vertical crosstalk degrades overall system performance.

Each of the vertical and horizontal crosstalk may further be divided into far end crosstalk and near end crosstalk. Near end crosstalk is crosstalk formed at the same end of a victim signal line at which a stimulus is input on an aggressor line. Near end crosstalk is generally illustrated as a level and is not cancellable. Rather, near end crosstalk generally enters the victim line and terminates. Far end crosstalk is crosstalk propagated on a victim line away from the end at which a stimulus is input on an aggressor. Far end crosstalk generally acts as a pulse and may be cumulative, negatively affecting the performance of a platform, such as a platform of a computing device.

Crosstalk may be reduced by increasing spacing, both between the vertical components and between the horizontal components. However, increasing the spacing may decrease routing density on a board or package, resulting in increased layer count and increased cost. In addition, vertical components cannot be easily spaced out due to size constraints. Vertical crosstalk may be reduced by adding more ground vertical components between the signal vertical components. However, adding more ground vertical components increases both the cost and size of the package and fails to completely eliminate the vertical component crosstalk.

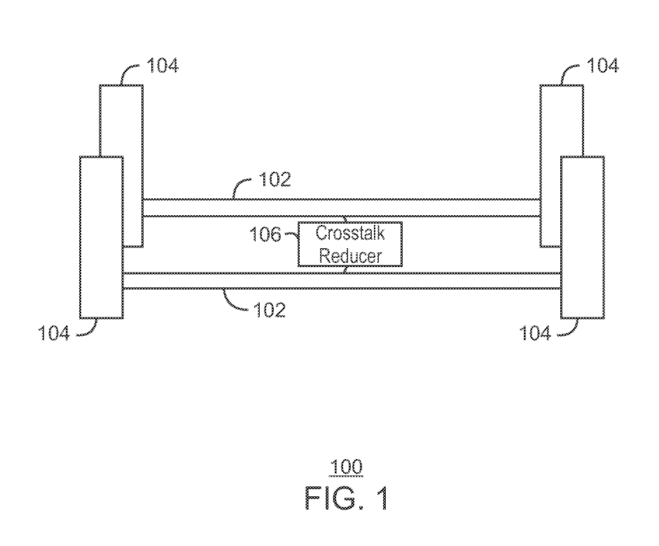

FIG. 1 is a diagram of a portion of a circuit board. Stripline topology 100 may include horizontal components 102 and vertical components 104. As used herein, the term horizontal refers to a component that remains within a single layer of a circuit board. The term vertical refers to a component that extends through multiple layers of a circuit board, generally in order to connect electrical components within the layers of the circuit board. The horizontal components 102 may be a signal line and may be made of any type of conducting material. For example, the horizontal components 102 may be signal lines, such as metal signal lines. The vertical components 104 may connect layers of horizontal components 102. For example, vertical components 104 may be conductors and may include vias, sockets, packages, or any similar components.

Horizontal crosstalk may occur between horizontal components 102. Vertical crosstalk may occur between vertical components 104. The polarity of the vertical crosstalk is opposite the polarity of a stimulus. The horizontal crosstalk will combine with the vertical crosstalk of the stripline topology. If the polarity of the horizontal crosstalk is also the opposite to the polarity of the stimulus, and therefore the same polarity as the vertical crosstalk, the horizontal and vertical crosstalk will add to each other and the crosstalk of the stripline system will increase. However, if the horizontal crosstalk is the opposite in polarity to the vertical crosstalk, the horizontal crosstalk will destructively combine with the vertical crosstalk and the crosstalk of the stripline topology will decrease, or even cease completely.

A crosstalk reducer 106 may be disposed between horizontal components 102. The crosstalk reducer 106 may be configured to reduce crosstalk. For example, the crosstalk reducer 106 may be configured to cancel at least some of the crosstalk between vertical components 104. In an example, the crosstalk reducer 106 may cancel crosstalk between vertical components 104 by increasing crosstalk between horizontal components 102. In some embodiments, the crosstalk reducer 106 may be a change in the properties of the materials of the circuit board, a variation in the geometry of the horizontal components 102, or some combination thereof.

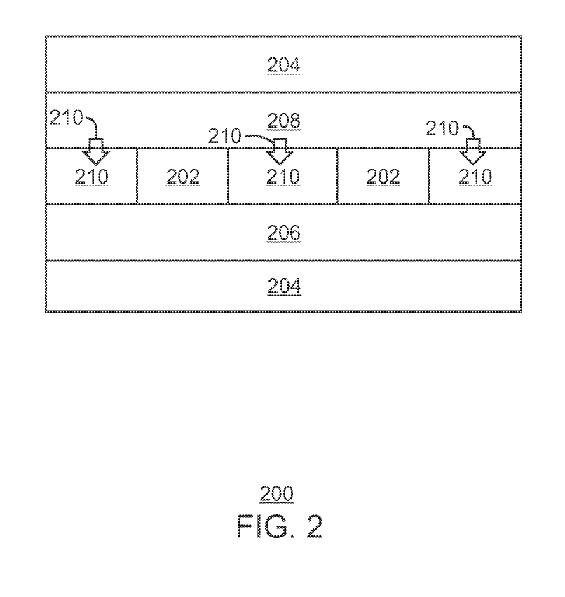

FIG. 2 is a cross-sectional view of a portion of a circuit board, illustrating a stripline. In an example, the circuit board 200 may be a printed circuit board (PCB). The circuit board 200 may be included in a host computing device, such as a laptop, a desktop, a mobile phone, a personal digital assistant, or any other type of computing device. The stripline 200 may include horizontal components, or signal lines, 202. In an example, signal lines 202 may be horizontal components 102. Signal lines 202 may be bracketed by ground layers 204, such that the signal lines 202 are completely enclosed. Dielectric layers 206 and 208 may be interposed between each ground layer 204 and the signal lines 202, such that the signal lines 202 are disposed on at least one dielectric layer, such as dielectric layer 206. In addition, resin 210 may be placed between the signal lines 202 and the dielectrics 206 and 208 due to manufacturing. The circuit board 200 may be symmetric, meaning the circuit board 200 may include an equal number of dielectric layers above and below the signal lines 202, or asymmetric, meaning the circuit board 200 may include an unequal number of dielectric layers either above or below the signal lines 202.

Dielectrics 206 and 208 may be a single material or a composite material. In an example, the dielectric layer may be a resin-impregnated cloth. In an example, the dielectrics 206 and 208 may be a composite of a glass, such as a woven glass, and a resin. In another example, the cloth may be a fiberglass and the resin may be an epoxy resin. Dielectrics 206 and 208 may be formed of the same material. In another example, dielectrics 206 and 208 may each be formed of a different material. Circuit board 200 may include multiple dielectric layers. For example, circuit board 200 may include two dielectric layers. In another example, circuit board 200 may include four, six, eight, or more dielectric layers.

A first dielectric layer 206 may be considered a laminate or core. The laminate may include a metallic layer overlaying a surface of the laminate. The metallic layer may be patterned, such as by etching, to form signal lines 202. In another example, the laminate may include individual signal lines overlaying the laminate. In a particular example, the laminate may be a fully cured resin/cloth, such as a resin/fiberglass weave, clad or laminated with etched sheets of copper foil. The remaining dielectric layers of the circuit board 200 may be a part of a prepreg. In an example, the prepreg may be partially cured resin-impregnated cloth. In another example, the prepreg may be partially cured epoxy resin impregnated with a fiberglass weave.

The resin 210 may flow between the signal lines 202 from the prepreg in the direction of the arrows 210 during the forming process. In an example, the resin 210 may be an epoxy resin. The resin may have a relative permittivity, ε. The permittivity of the resin may fall within a range, such as within a range of 2-7, 2.8-3.3, or 5-7. The permittivity of the resin may affect the polarity of the horizontal crosstalk. In an example, if the permittivity of the resin falls within a low range, such as 2-3, the polarity of the crosstalk of the circuit board 200 may be opposite that of the stimulus. For example, the polarity of the crosstalk of the circuit board 200 may be negative if the permittivity of the resin is low. This opposing crosstalk polarity may be caused by the difference in the permittivity of the resin as compared to the permittivity of the cloth, such as the resin-impregnated cloth. For example, the permittivity of a glass cloth typically falls within a range such as 5-7, as compared to the typical range of resin permittivity of 2-3. However, if the permittivity of the resin more closely matches the permittivity of the cloth, the polarity of the crosstalk may match the polarity of the stimulus.

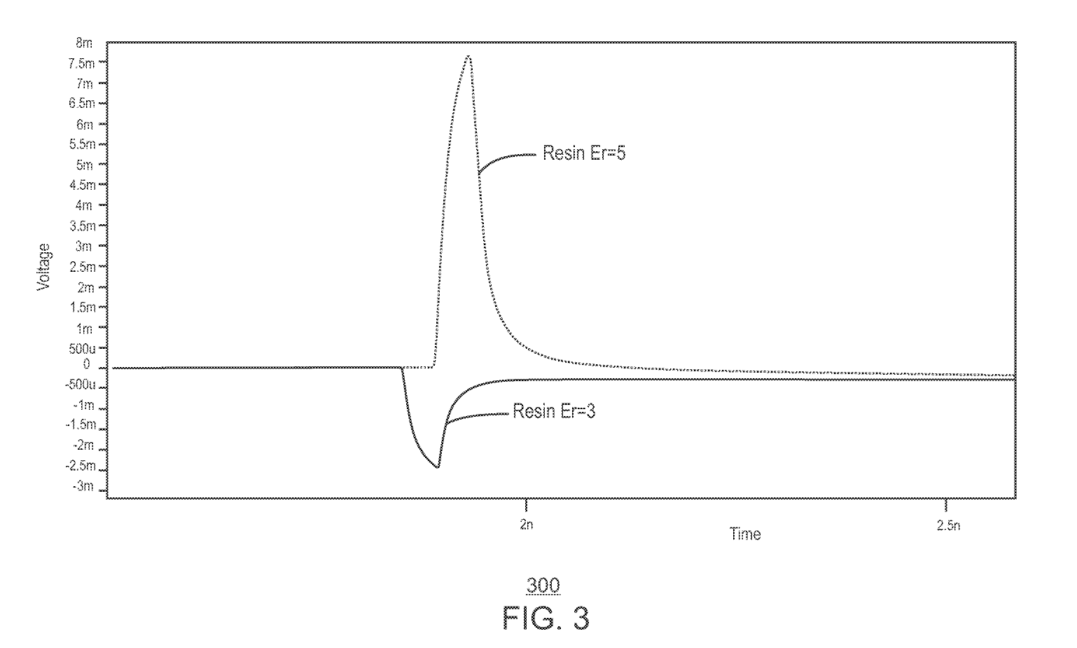

FIG. 3 is a graph illustrating the effect of the relative permittivity of resin on crosstalk polarity. The spacing of the signal lines was not changed during simulation. As shown in the graph, a resin with a permittivity of 3 will cause a negative crosstalk. However, a resin with a permittivity of 5 will cause a positive crosstalk. Therefore, by increasing the permittivity of the resin, such as to more closely match the permittivity of the cloth, the polarity of the crosstalk may be reversed. As such, the horizontal crosstalk may have a polarity opposite the polarity of the vertical crosstalk and may be used to cancel the vertical crosstalk.

The permittivity of the resin may be increased to match or exceed the permittivity of the glass. For example, the permittivity of the resin may be increased to greater than 5, such as within the range of 5-7. In an example, the permittivity of the resin may be increased to match the permittivity of the cloth. In another example, the permittivity of the resin may be increased to a larger permittivity than the cloth. In a further example, the permittivity of the resin may be raised, such as to above 5, while the permittivity of the cloth is lowered in order to prevent having to change the geometry of the signal lines. The permittivity of the resin may also be increased to more closely match or even exceed the permittivity of the laminate.

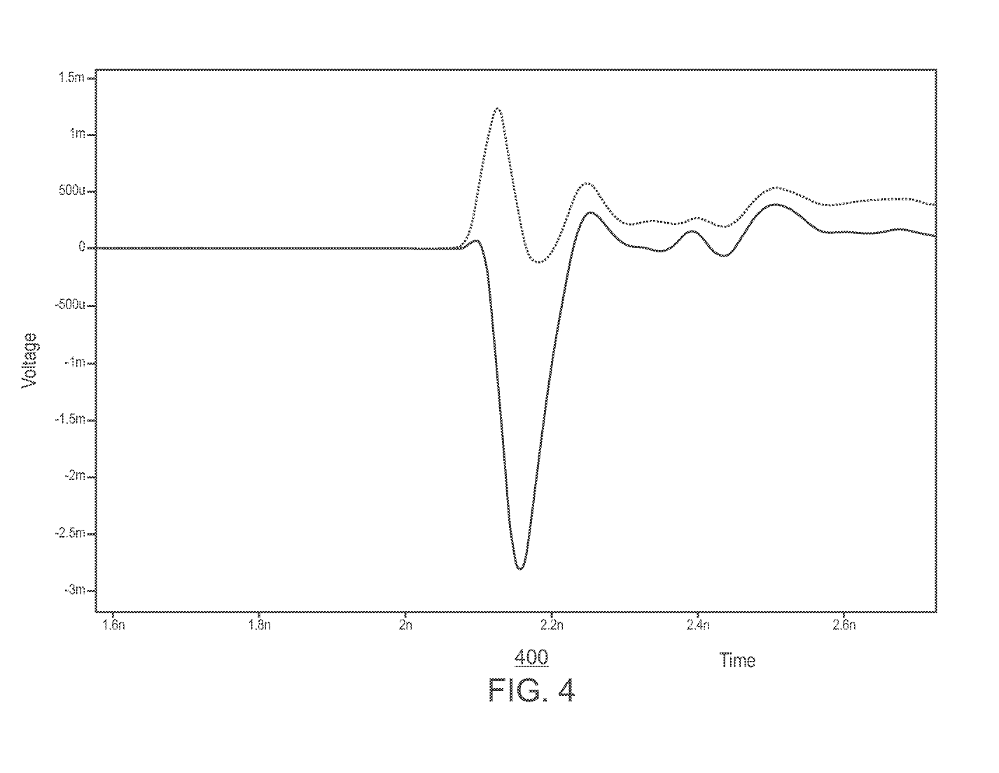

FIG. 4 is a graph illustrating the effect of signal line spacing on crosstalk polarity. The spacing of the signal lines in a circuit board may affect the polarity of the horizontal crosstalk. In particular, the polarity of the crosstalk may flip if the spacing is changed. In an example, the polarity of the crosstalk may flip from negative to positive as the distance between signal lines decreases. This example is illustrated in the graph. In particular, as the signal line spacing decreases from 12 mils to 8 mils, the polarity of the crosstalk may flip from negative to positive.

Decreasing the spacing between signal lines may be combined with increasing the permittivity of the resin to affect the polarity of the crosstalk. For example, increasing the permittivity of the resin may flip the polarity of the crosstalk, but the magnitude of the horizontal crosstalk may not be large enough to cancel the vertical crosstalk. However, by also decreasing the spacing between the signal lines, the magnitude of the now positive horizontal crosstalk may increase enough to substantially cancel at least some, if not all, of the vertical crosstalk.

The spacing between signal lines may be decreased by changing the geometry of the signal lines. For example, the geometry of the signal lines may be modified by the addition of stubs disposed on each of the signal lines. The addition of the stubs may create a stubby signal line. The stubby signal line may include longitudinal lengths interrupted by latitudinal increases to form the stubs. The stubs may be disposed on the signal lines such that the stubs extend from the signal lines in a variety of directions. In another example, the stubs may extend from the signal lines in a single direction. The signal lines may include a longitudinal length. The stubs may include a longitudinal section and a pair of latitudinal sections, and the stubs may be disposed along the length of the longitudinal signal lines such that the longitudinal sections of the stubs are parallel to the longitudinal signal lines. The length of the stubby signal line may be significantly increased compared to a non-stubby signal line. The stubs of the signal line may interlock with the stubs of an adjacent signal line. By interlocking the stubs of adjacent signal lines, the signal lines may be brought closer together over a greater length. This increase in closeness may cause the polarity of the horizontal crosstalk to flip, such as from positive to negative.

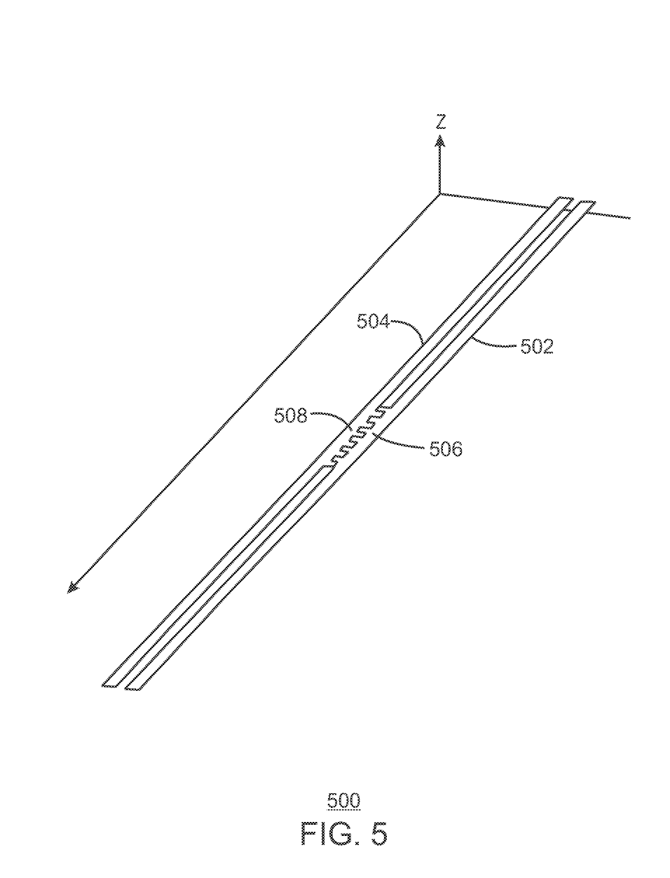

FIG. 5 is a schematic of a signal line including stubs. The stubs may be placed on the signal lines 502 and 504 in groups 506 and 508. In an example, the grouping of stubs 506 on signal line 502 may interlock with the grouping of stubs 508 on signal line 504. More than one grouping of stubs may be placed along the length of the signal line. The number and placement of the groups of stubs may be determined by a designer. For example, the number and placement of the stubs may be manually determined by a designer. In another example, the number and placement of the stubs may be calculated, such as by a designer or a computing device. For example, the optimal number and placement of the stubs may be calculated. In addition, the geometry of the stubs may be determined by a designer, such as manually or by calculation of an optimal shape.

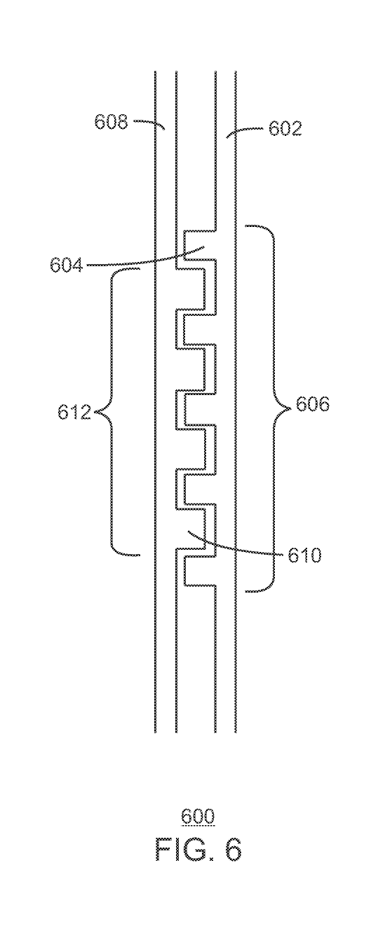

FIG. 6 is a top view of a stripline including stubs. The stripline may include signal lines sandwiched within a circuit board. Signal line 602 may include stubs 604. The stubs 604 may be disposed on the signal line 602 in a group 606. Signal line 608 may include stubs 610 disposed on the signal line in a group 612. The group of stubs 610 may be interlocked with the stubs of group 612. By interlocking the stubs of group 610 with the stubs of group 612, the signal lines 602 and 608 may be placed closer together over a greater length. By bringing the signal lines 602 and 608 closer over this greater length, the effects of low permittivity resin on horizontal crosstalk polarity may be overcome and the polarity may be reversed. By reversing the polarity of the horizontal crosstalk, the horizontal crosstalk may cancel at least some of the vertical crosstalk.

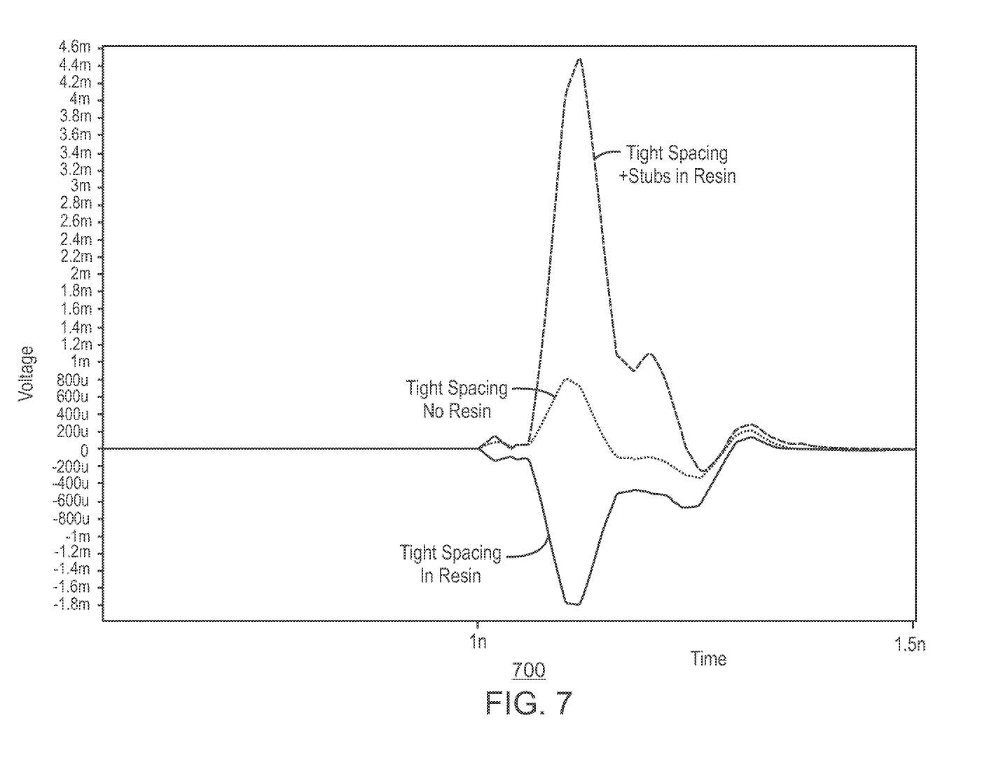

FIG. 7 is a graph illustrating the effects of the stubby line on horizontal crosstalk polarity. As shown in the graph, the addition of the stubby line may reverse the polarity of the horizontal crosstalk to a positive polarity. This positive crosstalk may have a magnitude large enough to overcome the effects of a low permittivity resin. In an example, the stubby line may be combined with a high permittivity resin to cause a horizontal crosstalk with a polarity opposite that of the vertical crosstalk. In addition, the combination of the stubby line with the high permittivity resin may increase the magnitude of the horizontal crosstalk enough to substantially cancel the vertical crosstalk.

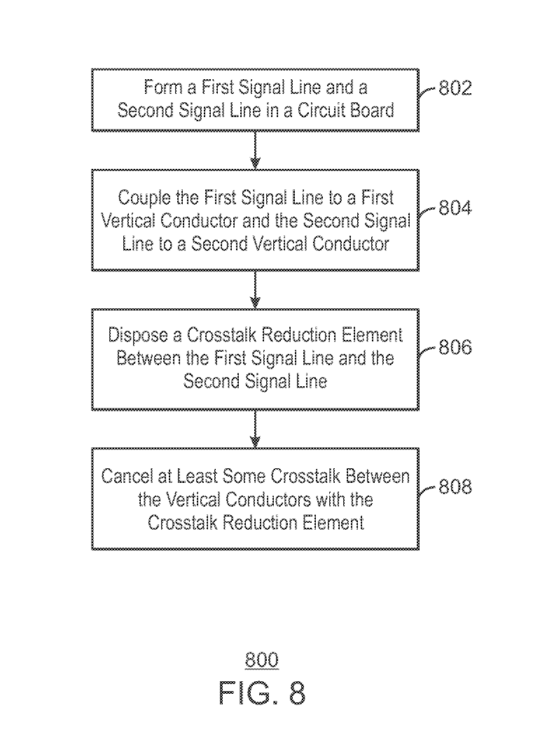

FIG. 8 is a process flow diagram of a method of forming a circuit board. The method 800 may begin at block 802 with forming a first signal line and a second signal line in a circuit board. The circuit board may be formed such that the signal lines are completely enclosed within the circuit board. For example, the signal lines may be sandwiched between dielectric layers. In an example, the signal lines may be formed by etching a metal layer disposed over a dielectric layer. In an example, the circuit board may include a single signal line. In another example, the circuit board may include multiple signal lines, such as two signal lines or more than two signal lines.

At block 804, the first signal line may be coupled, such as electrically coupled, to a first vertical component and the second signal line may be coupled to a second vertical component. The vertical components may be via, sockets, packages, or similar components. In an example, each signal line may be coupled to a single vertical component. In another example, each signal line may be coupled to multiple vertical components, such as two vertical components.

At block 806, a crosstalk reduction element may be disposed between the first signal line and the second signal line. In an example, a crosstalk reduction element may be disposed between each set of signal lines. For example, if a circuit board includes three signal lines, the circuit board may also include two crosstalk reduction elements, disposed between the three signal lines. In another example, the crosstalk reduction element may be a single element which affects the entire circuit board. For example, the crosstalk reduction element may be an increase in the permittivity of the resin within the circuit board. In another example, the crosstalk reduction element may be decreasing the spacing between signal lines. The spacing may be decreased by physically moving the signal lines closer together. In another example, the spacing may be decreased by disposing stubs on the signal lines. The stubs of a first signal line may interlock with the subs of a second signal line, such as an adjacent signal line.

At block 808, at least some crosstalk between the vertical components may be cancelled with the crosstalk reduction element. For example, the crosstalk reduction element may increase the horizontal crosstalk and cancel the vertical crosstalk with the horizontal crosstalk. The crosstalk reduction element may reverse the polarity of the horizontal crosstalk in order to cancel at least some of the vertical crosstalk with the horizontal crosstalk.

In the foregoing description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

An embodiment is an implementation or example. Reference in the specification to “an embodiment,” “one embodiment,” “some embodiments,” “various embodiments,” or “other embodiments” means that a particular feature, structure, or characteristic described in connection with the embodiments is included in at least some embodiments, but not necessarily all embodiments, of the inventions. The various appearances of “an embodiment,” “one embodiment,” or “some embodiments” are not necessarily all referring to the same embodiments. Elements or aspects from an embodiment can be combined with elements or aspects of another embodiment.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

It is to be noted that, although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the preceding description, various aspects of the disclosed subject matter have been described. For purposes of explanation, specific numbers, systems and configurations were set forth in order to provide a thorough understanding of the subject matter. However, it is apparent to one skilled in the art having the benefit of this disclosure that the subject matter may be practiced without the specific details. In other instances, well-known features, components, or modules were omitted, simplified, combined, or split in order not to obscure the disclosed subject matter.

While the disclosed subject matter has been described with reference to illustrative embodiments, this description is not intended to be construed in a limiting sense. Various modifications of the illustrative embodiments, as well as other embodiments of the subject matter, which are apparent to persons skilled in the art to which the disclosed subject matter pertains are deemed to lie within the scope of the disclosed subject matter.

While the present techniques may be susceptible to various modifications and alternative forms, the exemplary examples discussed above have been shown only by way of example. It is to be understood that the technique is not intended to be limited to the particular examples disclosed herein. Indeed, the present techniques include all alternatives, modifications, and equivalents falling within the true spirit and scope of the appended claims.

What is claimed is:

1. An apparatus, comprising:
a first signal line conductively coupled to a first vertical conductor;
a second signal line conductively coupled to a second vertical conductor; and
a crosstalk reduction element disposed between the first and second signal lines to cancel at least some of the crosstalk between the first and second vertical conductors.

2. The apparatus of claim 1, wherein the first signal line and the second signal line are disposed on a dielectric layer comprising a resin-impregnated cloth, wherein a permittivity of the resin is substantially equal to a permittivity of the resin-impregnated cloth.

3. The apparatus of claim 1, wherein the first signal line and the second signal line are disposed on a dielectric layer comprising a resin-impregnated cloth, wherein a permittivity of the resin is greater than a permittivity of the cloth.

4. The apparatus of claim 1, wherein the first signal line and the second signal line are disposed on a dielectric layer comprising a resin-impregnated cloth, wherein a relative permittivity of the resin is greater than 5.

5. The apparatus of claim 1, wherein the crosstalk reduction element comprises a stub section.

6. The apparatus of claim 5, wherein the stub section comprises a first group of stubs disposed on the first signal line, the first group of stubs interlocked with a second group of stubs on the second signal line.

7. The apparatus of claim 1, wherein the first vertical conductor and the second vertical conductor each comprise one or more of a via, a connector, and a socket.

8. The apparatus of claim 1, wherein the crosstalk reduction element increases crosstalk between the first signal line and the second signal line.

9. The apparatus of claim 1, wherein a spacing between the first signal line and the second signal line is decreased.

10. The apparatus of claim 1, wherein a spacing between the first signal line and the second signal line is at most 8 mils.

11. A computing device, comprising:
a circuit board coupled to the host computing system, the circuit board comprising:
a first signal line conductively coupled to a first vertical conductor;
a second signal line conductively coupled to a second vertical conductor; and
a crosstalk reduction element disposed between the first and second signal lines to cancel at least some of the crosstalk between the first and second vertical conductors.

12. The computing device of claim 11, wherein the first signal line and the second signal line are disposed on a dielectric layer comprising a resin-impregnated cloth, wherein a permittivity of the resin is substantially equal to a permittivity of the resin-impregnated cloth.

13. The computing device of claim 11, wherein the first signal line and the second signal line are disposed on a dielectric layer comprising a resin-impregnated cloth, wherein a permittivity of the resin is greater than a permittivity of the cloth.

14. The computing device of claim 11, wherein the first signal line and the second signal line are disposed on a dielectric layer comprising a resin-impregnated cloth, wherein a relative permittivity of the resin is greater than 5.

15. The computing device of claim 11, wherein the crosstalk reduction element comprises a stub section.

16. The computing device of claim 15, wherein the stub section comprises a first group of stubs disposed on the first signal line, the first group of stubs interlocked with a second group of stubs on the second signal line.

17. The computing device of claim 11, wherein the first vertical conductor and the second vertical conductor each comprise one or more of a via, a connector, and a socket.

18. The computing device of claim 11, wherein the crosstalk reduction element increases crosstalk between the first signal line and the second signal line.

19. The computing device of claim 11, wherein a spacing between the first signal line and the second signal line is at most 8 mils.

20. A method, comprising:
forming a first signal line on a circuit board, the first signal line to conductively couple to a first vertical conductor;
forming a second signal line on a circuit board, the second signal line to conductively couple to a second vertical conductor; and
disposing a crosstalk reduction element between the first and second signal lines to cancel at least some of the crosstalk between the first and second vertical conductors.

21. The method of claim 20, comprising disposing the first signal line and the second signal line on a dielectric layer comprising a resin-impregnated cloth, wherein a permittivity of the resin is substantially equal to a permittivity of the resin-impregnated cloth.

22. The method of claim 20, comprising disposing the first signal line and the second signal line on a dielectric layer comprising a resin-impregnated cloth, wherein a permittivity of the resin is greater than a permittivity of the cloth.

23. The method of claim 20, comprising disposing the first signal line and the second signal line on a dielectric layer comprising a resin-impregnated cloth, wherein a relative permittivity of the resin is greater than 5.

24. The method of claim 20, wherein the crosstalk reduction element comprises a stub section.

25. The method of claim 24, wherein the stub section comprises a first group of stubs disposed on the first signal line, the first group of stubs interlocked with a second group of stubs on the second signal line.

26. The method of claim 20, wherein the first vertical conductor and the second vertical conductor each comprise one or more of a via, a connector, and a socket.

27. The method of claim 20, wherein the crosstalk reduction element increases crosstalk between the first signal line and the second signal line.

28. The method of claim 20, comprising decreasing a spacing between the first signal line and the second signal line.

29. The method of claim 20, wherein a spacing between the first signal line and the second signal line is at most 8 mils.
